(19) United States
(12) Patent Application Publication
(10) Pub. No.: US 2026/0218814 A1
(43) Pub. Date: Jul. 30, 2026

(54) SELF-CENTERING PLUG

(71) Applicant: Microsoft Technology Licensing, LLC, Redmond, WA (US)

(72) Inventor: Errol Mark TAZBAZ, Bellevue, WA (US)

(73) Assignee: Microsoft Technology Licensing, LLC, Redmond, WA (US)

(21) Appl. No.: 19/041,294

(22) Filed: Jan. 30, 2025

(51) Int. Cl. F16L 3/205; F16L 37/60

(52) U.S. Cl. CPC F16L 3/205; F16L 37/60

(57) ABSTRACT

A self-centering plug for transferring fluid comprises an elongated body comprising an annular surface extending from an outer surface. A washer is located between the annular surface and an annular wall of a housing, with the housing enclosing a portion of the elongated body. A float spring encircles the elongated body and comprises a distal spring end abutting an annular shoulder of the elongated body and a proximal spring end retained in the housing, wherein the float spring urges the annular surface of the elongated body into contact with the washer.

### BACKGROUND

When connecting fluid supply lines, improper matings of plugs with sockets can disrupt fluid transfer.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed and further described below that relate to self-centering plugs for transferring fluids and related methods for aligning a self-centering plug with a socket. In one example and as described below, a self-centering plug for transferring fluid comprises an elongated body comprising an annular surface extending from an outer surface of the elongated body. A washer is located between the annular surface and an annular wall of a housing, with the housing enclosing a portion of the elongated body. A float spring encircles the elongated body and comprises a distal spring end abutting an annular shoulder of the elongated body and a proximal spring end retained in the housing, wherein the float spring urges the annular surface of the elongated body into contact with the washer.

### BRIEF DESCRIPTION OF THE DRAWINGS

FIG. 1 shows a portion of a self-centering plug extending from a housing within a chassis of a modular computing unit according to one example of the present disclosure.

FIG. 2 shows a cross-section view along line 2-2 of FIG. 1 of the self-centering plug in a centered position and adjacent a socket.

FIG. 3 shows a partial cross-section view of the self-centering plug of FIG. 2.

FIG. 4 shows the self-centering plug of FIG. 2 contacting an edge of the socket at an angle according to examples of the present disclosure.

FIG. 5 shows the self-centering plug of FIG. 2 displaced from the centered position as the plug advances into the socket.

FIG. 6 shows the self-centering plug of FIG. 5 advanced further into the socket.

FIG. 7 shows another example of the self-centering plug displaced from the centered position as the plug advances into the socket.

FIG. 8 shows an exploded view of the self-centering plug according to examples of the present disclosure.

FIGS. 9A and 9B are a flow chart of a method for aligning a self-centering plug with a socket according to examples of the present disclosure.

### DETAILED DESCRIPTION

Fluid delivery systems, such as cooling systems for data center hardware, can utilize plugs and corresponding sockets for connecting and disconnecting fluid supply lines. Improper matings of plugs and sockets can disrupt fluid transfer. In some examples, plugs for such systems can utilize a centering mechanism that counteracts the force of gravity to maintain the plug in a centered position. However, such mechanisms create other drawbacks, such as allowing or requiring axial movement of the plug which can cause undesirable buckling in downstream hoses and/or other components. These mechanisms also couple the radial and angular accommodation of the plug. In these examples, as one component of accommodation increases the other component of accommodation can be correspondingly limited. Additionally, such mechanisms require larger packaging space, thereby limiting the maximum fluidic coupling size that may be utilized within a given enclosure. In some examples, these mechanisms also require changes in plug and socket lengths when the fluidic coupling size changes. These changes then require corresponding changes in mounting hardware for the plug and/or socket, which increases the complexity, cost and time required to change a fluidic coupling size.

Accordingly and as described in more detail below, the present disclosure describes self-centering plugs and corresponding methods for aligning a self-centering plug with a socket that overcome one or more of the disadvantages described above. Advantageously, self-centering plugs of the present disclosure provide independent radial and angular accommodation, decoupled from one another, to enable maximum angular accommodation and maximum radial accommodation simultaneously. Additionally, self-centering plugs of the present disclosure maintain a fixed length regardless of loading condition to advantageously avoid imparting any compressive load on a connected hose or other downstream components. Further, the self-centering plugs of the present disclosure enable an interchangeable family of coupling sizes to fit within a given enclosure size, thereby greatly simplifying the process of changing a fluidic coupling size.

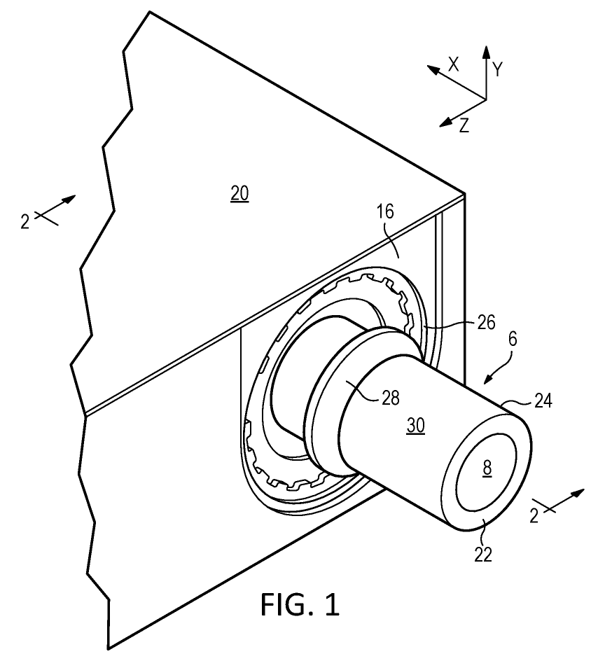

FIGS. 1-8 show one example of a self-centering plug 6 for transferring fluid according to aspects of the present disclosure. In the present example the self-centering plug 6 is configured to be coupled to a hose 10 at a distal end and removably mated with a socket 12 at a proximal end. More particularly and as described in more detail below, the self-centering plug 6 is configured to align with a centerline socket axis of the socket 12 by radially and/or angularly displacing an elongated body of the plug from a centered position. It will be appreciated that the principles of the present disclosure can be utilized in other configurations of self-centering plugs having different form factors, capabilities, components, and/or other features.

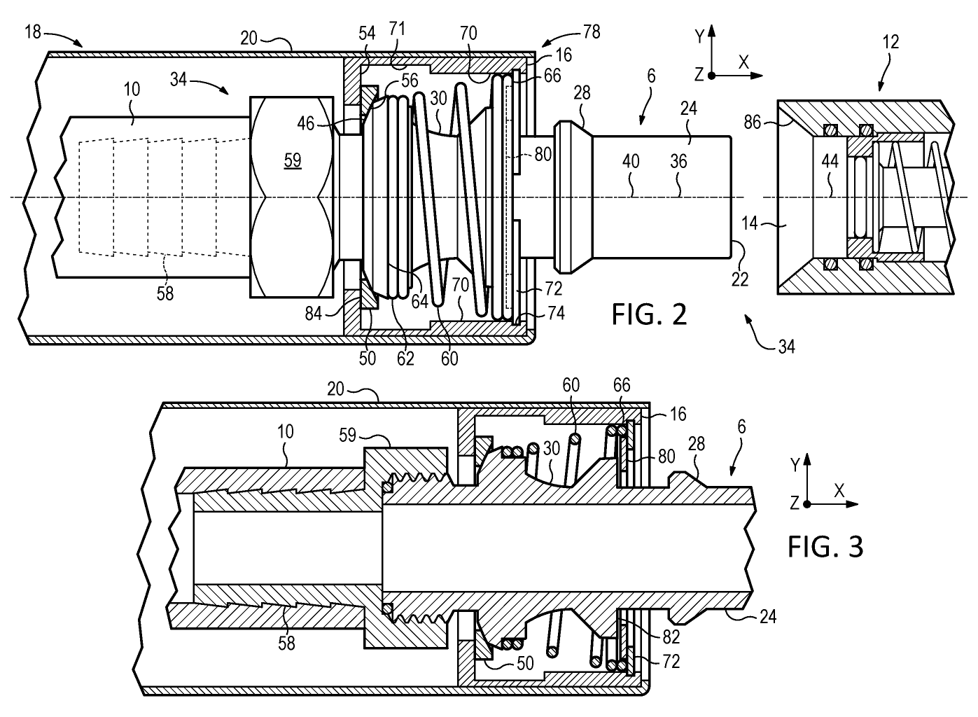

In the present example and with reference to FIG. 1, self-centering plug 6 resides in a housing 16 that is mounted inside a chassis 20 of a modular computing unit, such as a blade server. The self-centering plug 6 is mounted such that the proximal end 22 of an elongated body 24 of the plug extends from an aperture 26 of the housing 16 for insertion into a corresponding socket 12 (see FIG. 2). In this example, self-centering plug 6 includes a plug moving seal 8 configured to move axially in the X-axis direction when the plug is mated with a corresponding socket, to thereby allow fluid flow through the plug. In this example, self-centering plug 6 includes a hand-mating barb 28 extending from an outer surface 30 of the plug to allow connection of the plug with a test socket, hose, or other component when the blade server is removed from a server rack.

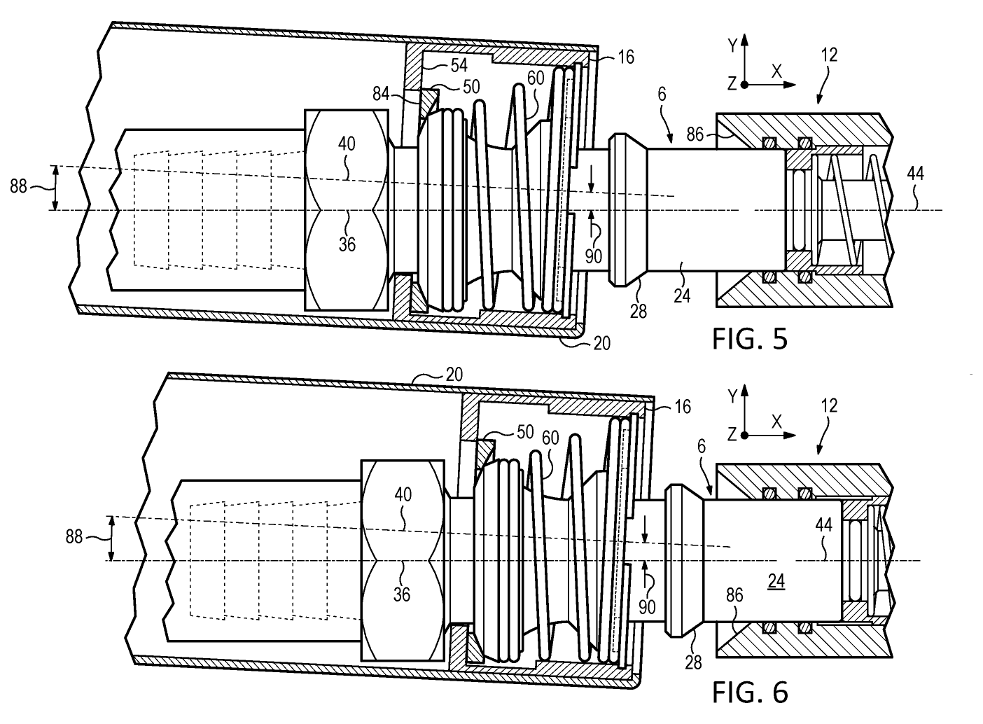

With reference now to FIG. 2, self-centering plug 6 is shown in a centered position 34 within housing 16. In this position and as described in more detail below, a centerline plug axis 36 defining the centerline of the elongated body 24 is colinear with a centerline housing axis 40 of the housing 16 (see also FIG. 5) defining the centerline of the housing. In the example of FIG. 2, self-centering plug 6 in the centered position 34 is also aligned with the centerline socket axis 44 of the socket 12.

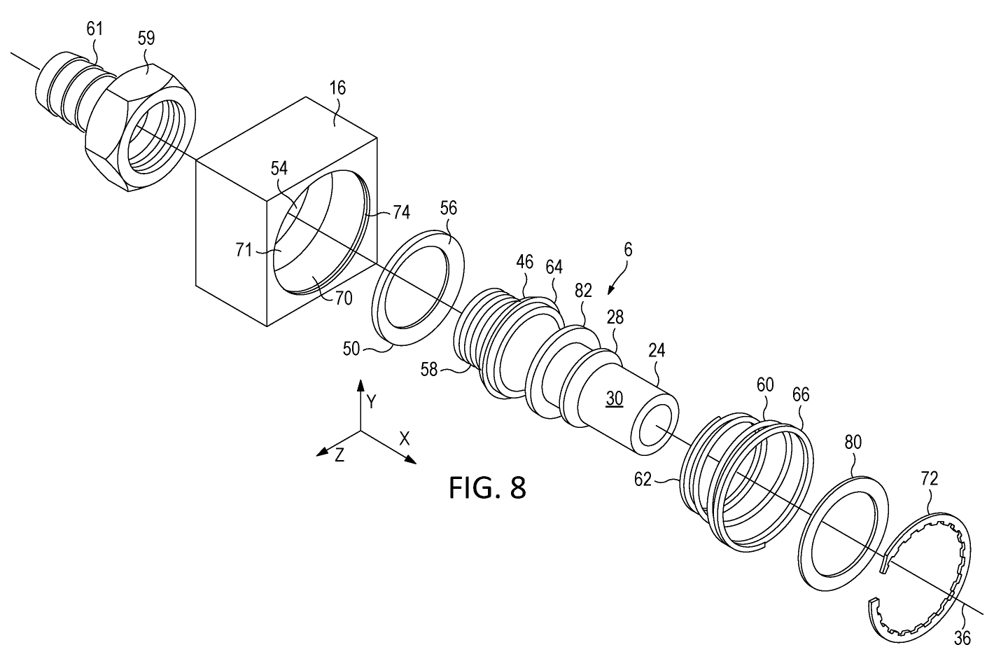

As described in more detail below and with reference also to FIG. 8, the elongated body 24 of self-centering plug 6 comprises an annular surface 46 extending from the outer surface 30 of the elongated body. As shown in FIG. 2, a washer 50 is positioned between the annular surface 46 and an annular wall 54 extending inwardly in the housing. In one potential advantage of the present configuration, and as described in more detail below, annular surface 46 of self-centering plug 6 is arcuate, in this example convexly spherical, and washer 50 includes a corresponding arcuate washer surface 56, in this example a concave spherical surface, that is configured for relative movement against the arcuate annular surface of the plug. Advantageously, this configuration provides a self-centering function to the plug 6 and enables 360-degree radial movement of the plug (generally in the Y and Z axes) relative to the washer 50 and housing 16. In a similar manner and as described further below, washer 50 can move radially 360-degrees relative to the annular wall 54 and housing 16, thereby providing additional radial accommodation to the self-centering plug 6.

With reference to FIG. 2, annular wall 54 of housing 16 defines an opening through which a distal end of the elongated body 24 extends. With reference also to FIG. 8, distal end of the elongated body 24 includes threads 58, and a hose barb 59 is threaded onto the distal end of the body. Hose barb 59 includes ridges 61 that secure hose 10 onto the hose barb.

In another potential advantage of the present disclosure, a float spring 60 encircles elongated body 24 and comprises a distal spring end 62 abutting an annular shoulder 64 of the elongated body, and a proximal spring end 66 retained in the housing 16. The float spring 60 is compressively preloaded to urge the annular surface 46 of the elongated body 24 into contact with the washer surface 56 of washer 50. Advantageously, the compressively preloaded float spring 60 provides a radial and angular restoring force that overcomes the downward gravitational pull to maintain the self-centering plug 6 in the centered position 34. Advantageously, this self-centering feature reduces the required tolerance loop with respect to a receiving aperture 14 of mating socket 12.

Additionally, washer 50, annular surface 46 of elongated body 24, and float spring 60 cooperate to enable independent radial movement and independent angular movement of the elongated body of the self-centering plug 6. In this manner and as described further below, this configuration enables the self-centering plug to have full radial accommodation and full angular accommodation simultaneously, in contrast to prior designs in which radial and angular accommodation are coupled in a manner that restricts the extent of one or both accommodations. Advantageously, the present configuration allows both radial and angular mismatch between the self-centering plug 6 and socket 12, with increasing mismatch causing greater deformation in float spring 60 and corresponding greater angular and/or radial restoring force tending to recenter the plug into its centered position 34.

In the present configuration, proximal spring end 66 of float spring 60 abuts an interior surface 70 of housing 16 to radially constrain and prevent radial movement of the proximal spring end of the float spring. With reference also to FIG. 8, in this example a spring retention clip 72 is seated in groove 74 defined in the interior surface 70 of the housing 16 at a proximal housing end 78 of the housing. The proximal spring end 66 of the float spring 60 abuts the spring retention clip 72 to prevent axial movement of the proximal spring end of the spring.

In this configuration and with reference also to FIG. 3, a plug retention washer 80 is radially constrained between the inside of the proximal spring end 66 of float spring 60 and the outer diameter of the elongated body 24. The plug retention 80 washer radially limits the excursion of elongated body 24 and also inhibits the body from being axially removed from the housing 16 as plug retention shoulder 82 extending from the outer surface 30 of the plug is unable to pass the plug retention washer. In a similar manner at the opposite end of the elongated body 24 and with reference again to FIG. 2, a distal face 84 of washer 50 abuts the annular wall 54 of the housing 16 to prevent axial movement of the elongated body toward the distal housing end 18 of housing 16. Accordingly and as described in the use case examples provided below, this configuration prevents axial movement of the elongated body 24 relative to housing 16, while still providing the elongated body with freedom of movement radially and angularly.

Advantageously, by preventing axial movement of the elongated body 24 relative to housing 16, the present configuration avoids the need for other components, such as overmate springs, that are required by other designs to manage axial misalignment and which can add significant axial loads to the system and related components. Further, because the elongated body 24 is axially constrained, the axial length of the downstream hose 10 does not change during insertion and mating of the elongated body with socket 12, thereby avoiding undesirable compressive forces and potential buckling of the hose. Accordingly, by axially constraining the elongated body 24 relative to housing 16, the present configuration provides the elongated body with radial and angular accommodation without creating additional axial forces on the elongated body and other components.

In the present example, a distal diameter of the distal spring end 62 of float spring 60 is less than a proximal diameter of the proximal spring end 66 of the float spring. With this configuration and as described further below, float spring 60 provides a self-centering restoring force to elongated body 24 while also enabling fully-decoupled radial and angular movement of the elongated body. More particularly, float spring 60 provides a radial restoring force to the elongated body 24 when the elongated body is radially displaced from the centerline housing axis 40 of the housing 16 (see FIG. 5). Similarly, float spring 60 provides an angular restoring force to the elongated body when the elongated body is angularly displaced from the centerline housing axis 40 of the housing 16.

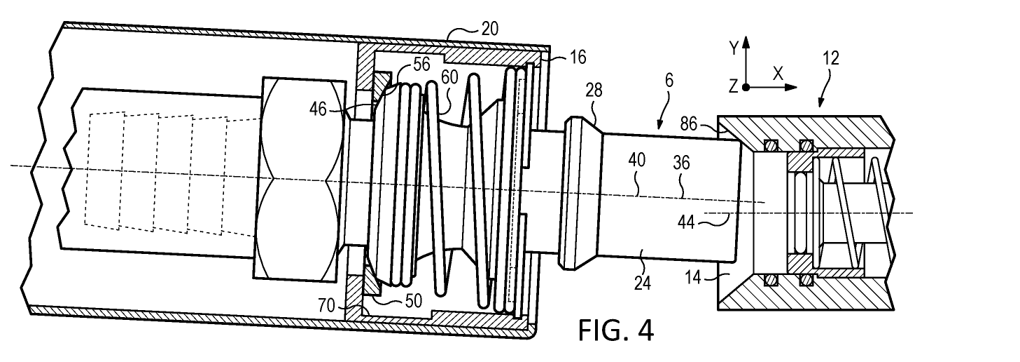

With reference now to FIG. 4, in some examples the self-centering plug 6 and housing 16 approach aperture 14 of socket 12 in an orientation in which the centerline plug axis 36 and colinear centerline housing axis 40 are misaligned with respect to the centerline socket axis 44 of socket 12. In some examples and as noted above, housing 16 is fixedly mounted inside a chassis 20 of a modular computing unit, such as a blade server. Socket 12 can be fluidically coupled to a manifold, a reservoir of coolant fluid, and a pump. Self-centering plug 6 and hose 10 are configured to receive coolant from socket 12 (or discharge circulated coolant to the socket) and circulate the coolant through the chassis 20 to absorb and dissipate heat from CPUs, GPUs, and/or other components.

In these examples, chassis 20 of the computing unit is removably mounted within a server rack, such as on rails, in a manner that allows the chassis to be inserted and removed from the rack. Housing 16 is fixedly mounted to chassis 20 and constrained from movement. With reference to FIGS. 4 and 5, as chassis 20, housing 16, and self-centering plug 6 are advanced axially (in the positive X-axis direction) toward socket 12, a chamfered edge 86 of socket 12 guides proximal end 22 of elongated body 24 into the receiving end of the socket. Advantageously, as the elongated body 24 is guided into the socket 12, the float spring 60, arcuate annular surface 46 of elongated body 24, and arcuate washer surface 56 of washer 50 enable the elongated body to shift radially and angularly with respect to housing 16 to bring centerline plug axis 36 of self-centering plug 6 into colinear alignment with centerline socket axis 44 of the socket.

As depicted in FIGS. 4 and 5, as the elongated body 24 is guided into socket 12, arcuate annular surface 46 of elongated body 24 slides relative to arcuate washer surface 56 of washer 50. Additionally in this example, distal face 84 of washer 50 translates relative to annular wall 54 of housing 16 to provide additional movement of the elongated body 24 relative to the housing. In other examples, annular surface 46 of elongated body 24 can slide relative to arcuate washer surface 56 of washer 50 while distal face 84 of washer 50 does not move relative to annular wall 54 of housing 16. In other examples, distal face 84 of washer 50 translates relative to annular wall 54 of housing 16 while annular surface 46 of elongated body 24 does not move relative to arcuate washer surface 56 of washer 50.

In the example of FIG. 5, elongated body 24 and its centerline plug axis 36 are angularly displaced from centerline housing axis 40 of housing 16 by an angle 88. In some examples, a maximum angular displacement from centerline housing axis 40 is approximately 2.5 degrees. In other examples, a maximum angular displacement can be less than or greater than 2.5 degrees. Also in this example, elongated body 24 and its centerline plug axis 36 are radially displaced (in the negative Y-axis direction) from its centered position 34 (see FIG. 4) by a distance 90 (in this example measured at the proximal end 78 of housing 16). In some examples, a maximum radial displacement from centerline housing axis 40 is approximately 3 mm. In other examples, a maximum radial displacement can be less than or greater than 3 mm. Additionally and with reference again to FIG. 2, interior surface 71 of housing 16 can function as a travel stop feature to limit the radial excursion of the washer 50.

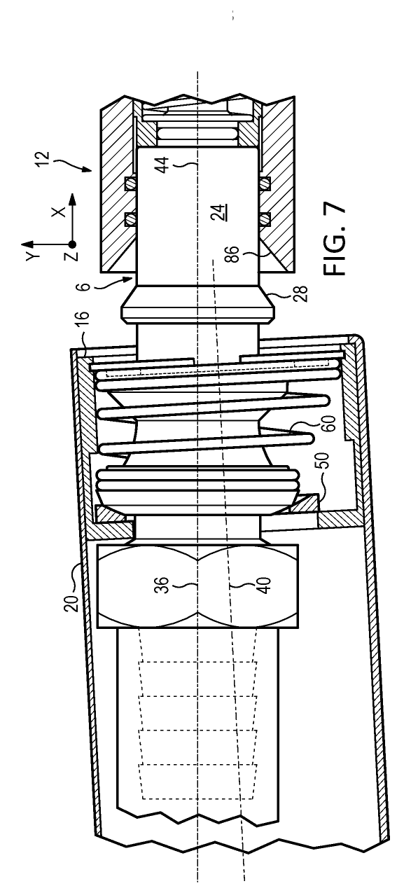

With reference to FIG. 6, as the elongated body 24 advances into socket 12, a socket fixed seal (not shown) contacts plug moving seal 8 to cause plug moving seal to move axially relative to elongated body 24 and allow fluid flow through the plug. With reference to FIG. 7, another example showing elongated body 24 radially and angularly displaced within housing 16 in a different direction is depicted.

In another potential advantage of the present disclosure, configurations of self-centering plug 6 can be utilized with two or more sizes of elongated bodies 24 having different bore diameters to provide different coolant flow volumes and rates through the bodies. In some examples, an overall axial length of self-centering plug 6 is fixed across a plurality of plugs having different bore diameters. Advantageously, multiple self-centering plugs 6 with different bore diameters can be utilized in the same housing 16 and chassis 20, such as a 1 RU (rack unit) height chassis (equal to 44.45 mm), thereby enabling easy modification of flow volumes by using a different self-centering plug having a different bore diameter.

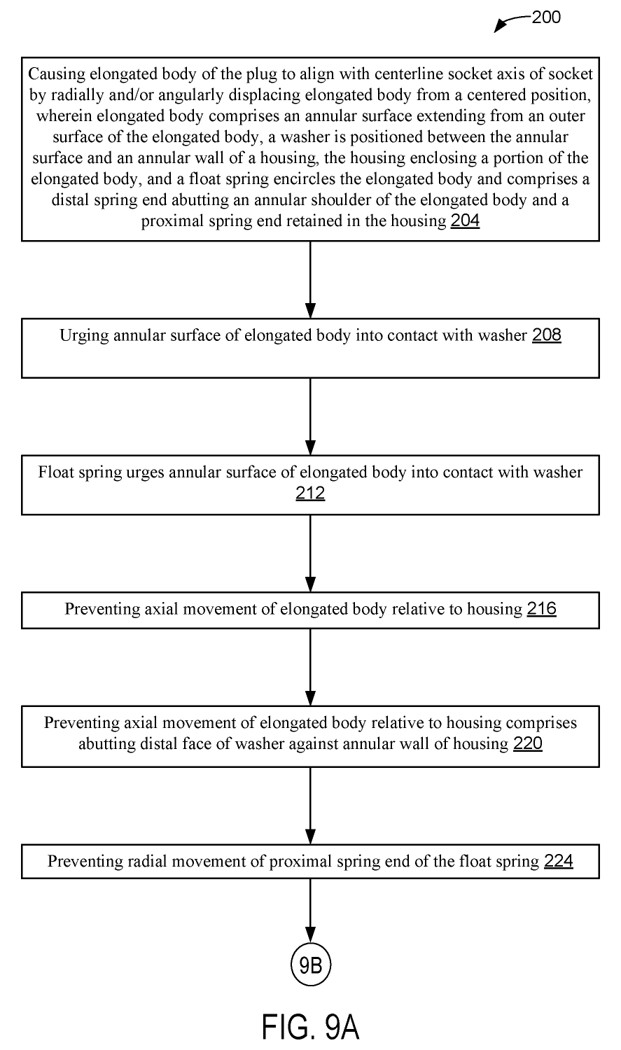

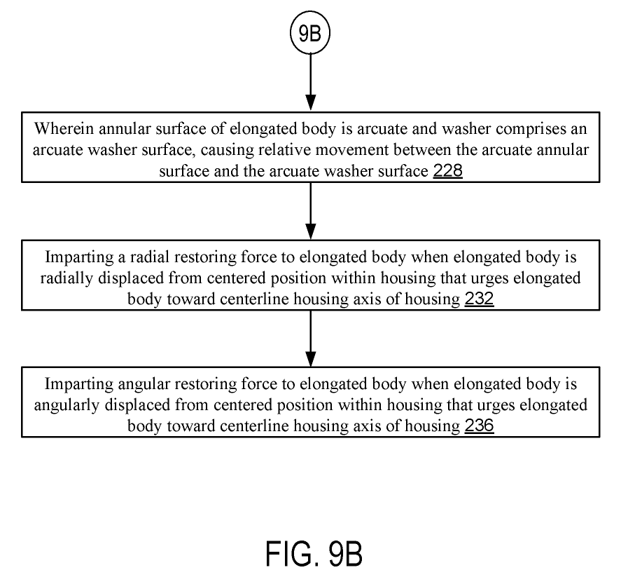

With reference now to FIGS. 9A and 9B, a flow diagram is provided depicting an example method 200 for aligning a self-centering plug with a socket. The following description of method 200 is provided with reference to the configurations and components described herein and shown in FIGS. 1-8. In other examples, method 200 can be performed with other configurations of self-centering plugs and in other contexts using other suitable components.

At 204 method 200 includes causing an elongated body of the plug to align with a centerline socket axis of the socket by radially and/or angularly displacing the elongated body from a centered position, wherein the elongated body comprises an annular surface extending from an outer surface of the elongated body, a washer is positioned between the annular surface and an annular wall of a housing, the housing enclosing a portion of the elongated body, and a float spring encircles the elongated body and comprises a distal spring end abutting an annular shoulder of the elongated body and a proximal spring end retained in the housing. At 208 method 200 includes urging the annular surface of the elongated body into contact with the washer. At 212 method 200 includes wherein the float spring urges the annular surface of the elongated body into contact with the washer.

At 216 method 200 includes preventing axial movement of the elongated body relative to the housing. At 220 method 200 includes wherein preventing axial movement of the elongated body relative to the housing comprises abutting a distal face of the washer against the annular wall of the housing. At 224 method 200 includes preventing radial movement of the proximal spring end of the float spring. With reference now to FIG. 9B, at 228 method 200 includes, wherein the annular surface of the elongated body is arcuate and the washer comprises an arcuate washer surface, causing relative movement between the arcuate annular surface and the arcuate washer surface.

At 232 method 200 includes imparting a radial restoring force to the elongated body when the elongated body is radially displaced from the centered position within the housing that urges the elongated body toward a centerline housing axis of the housing. At 236 method 200 includes imparting an angular restoring force to the elongated body when the elongated body is angularly displaced from the centered position within the housing that urges the elongated body toward a centerline housing axis of the housing.

The following paragraphs provide additional support for the claims of the subject application. One aspect provides a self-centering plug for transferring fluid, the self-centering plug comprising: an elongated body comprising an annular surface extending from an outer surface of the elongated body; a washer between the annular surface and an annular wall of a housing, the housing enclosing a portion of the elongated body; and a float spring encircling the elongated body and comprising a distal spring end abutting an annular shoulder of the elongated body and a proximal spring end retained in the housing, wherein the float spring urges the annular surface of the elongated body into contact with the washer. The self-centering plug may additionally or alternatively include, wherein the annular surface is arcuate and the washer comprises an arcuate washer surface configured for relative movement against the arcuate annular surface of the elongated body. The self-centering plug may additionally or alternatively include, wherein the float spring provides a radial restoring force to the elongated body when the elongated body is radially displaced from a centerline housing axis of the housing. The self-centering plug may additionally or alternatively include, wherein the float spring provides an angular restoring force to the elongated body when the elongated body is angularly displaced from a centerline housing axis of the housing. The self-centering plug may additionally or alternatively include, wherein a distal diameter of the distal spring end of the float spring is less than a proximal diameter of the proximal spring end of the float spring. The self-centering plug may additionally or alternatively include, wherein the proximal spring end of the float spring abuts an interior surface of the housing to prevent radial movement of the proximal spring end of the float spring. The self-centering plug may additionally or alternatively include, wherein the washer, annular surface of the elongated body, and float spring cooperate to enable independent radial movement and independent angular movement of the elongated body. The self-centering plug may additionally or alternatively include, wherein a distal face of the washer abuts the annular wall of the housing to prevent axial movement of the elongated body toward a distal housing end of housing. The self-centering plug may additionally or alternatively include a plug retention washer radially constrained between the proximal spring end of the float spring and the elongated body. The self-centering plug may additionally or alternatively include a spring retention clip seated in groove defined in an interior surface of the housing at a proximal housing end of the housing, wherein the proximal spring end of the float spring abuts the spring retention clip.

Another aspect provides a method for aligning a self-centering plug with a socket, the method comprising: causing an elongated body of the plug to align with a centerline socket axis of the socket by radially and/or angularly displacing the elongated body from a centered position, wherein the elongated body comprises an annular surface extending from an outer surface of the elongated body, a washer is positioned between the annular surface and an annular wall of a housing, the housing enclosing a portion of the elongated body, and a float spring encircles the elongated body and comprises a distal spring end abutting an annular shoulder of the elongated body and a proximal spring end retained in the housing. The method may additionally or alternatively include urging the annular surface of the elongated body into contact with the washer. The method may additionally or alternatively include, wherein the float spring urges the annular surface of the elongated body into contact with the washer. The method may additionally or alternatively include preventing axial movement of the elongated body relative to the housing. The method may additionally or alternatively include, wherein preventing axial movement of the elongated body relative to the housing comprises abutting a distal face of the washer against the annular wall of the housing. The method may additionally or alternatively include preventing radial movement of the proximal spring end of the float spring. The method may additionally or alternatively include, wherein the annular surface of the elongated body is arcuate and the washer comprises an arcuate washer surface, the method further comprising causing relative movement between the arcuate annular surface and the arcuate washer surface. The method may additionally or alternatively include imparting a radial restoring force to the elongated body when the elongated body is radially displaced from the centered position within the housing that urges the elongated body toward a centerline housing axis of the housing. The method may additionally or alternatively include imparting an angular restoring force to the elongated body when the elongated body is angularly displaced from the centered position within the housing that urges the elongated body toward a centerline housing axis of the housing.

Another aspect provides a self-centering plug for transferring fluid, the self-centering plug comprising: an elongated body comprising an arcuate annular surface extending from an outer surface of the elongated body; a washer comprising an arcuate washer surface contacting the arcuate annular surface, the washer located between the arcuate annular surface and an annular wall of a housing, the housing enclosing a portion of the elongated body; and a float spring encircling the elongated body and comprising a distal spring end abutting an annular shoulder of the elongated body and a proximal spring end retained in the housing, wherein the float spring urges the annular surface of the elongated body into contact with the arcuate washer surface of the washer to provide a radial restoring force and an angular restoring force to the elongated body when the elongated body is radially displaced and angularly displaced from a centerline housing axis of the housing.

"And/or" as used herein is inclusive and means either one or both of the items/conditions connected by the phrase. In other words, when A "and/or" B is used, it means A alone, or B alone, or both A and B together.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed. In the descriptions provided herein, ordinal numbers such as first and second are used for convenience and ease of description, and do not denote any order or arrangement of components.

The subject matter of the present disclosure includes all novel and non-obvious combinations and sub-combinations of the various processes, systems and configurations, and other features, functions, acts, and/or properties disclosed herein, as well as any and all equivalents thereof.

1. A self-centering plug for transferring fluid, the self-centering plug comprising:
an elongated body comprising an annular surface extending from an outer surface of the elongated body;
a washer between the annular surface and an annular wall of a housing, the housing enclosing a portion of the elongated body; and
a float spring encircling the elongated body and comprising a distal spring end abutting an annular shoulder of the elongated body and a proximal spring end retained in the housing, wherein the float spring urges the annular surface of the elongated body into contact with the washer.

2. The self-centering plug of claim 1, wherein the annular surface is arcuate and the washer comprises an arcuate washer surface configured for relative movement against the arcuate annular surface of the elongated body.

3. The self-centering plug of claim 1, wherein the float spring provides a radial restoring force to the elongated body when the elongated body is radially displaced from a centerline housing axis of the housing.

4. The self-centering plug of claim 1, wherein the float spring provides an angular restoring force to the elongated body when the elongated body is angularly displaced from a centerline housing axis of the housing.

5. The self-centering plug of claim 1, wherein a distal diameter of the distal spring end of the float spring is less than a proximal diameter of the proximal spring end of the float spring.

6. The self-centering plug of claim 1, wherein the proximal spring end of the float spring abuts an interior surface of the housing to prevent radial movement of the proximal spring end of the float spring.

7. The self-centering plug of claim 1, wherein the washer, annular surface of the elongated body, and float spring cooperate to enable independent radial movement and independent angular movement of the elongated body.

8. The self-centering plug of claim 1, wherein a distal face of the washer abuts the annular wall of the housing to prevent axial movement of the elongated body toward a distal housing end of housing.

9. The self-centering plug of claim 1, further comprising a plug retention washer radially constrained between the proximal spring end of the float spring and the elongated body.

10. The self-centering plug of claim 1, further comprising a spring retention clip seated in groove defined in an interior surface of the housing at a proximal housing end of the housing, wherein the proximal spring end of the float spring abuts the spring retention clip.

11. A method for aligning a self-centering plug with a socket, the method comprising:
causing an elongated body of the plug to align with a centerline socket axis of the socket by radially and/or angularly displacing the elongated body from a centered position, wherein the elongated body comprises an annular surface extending from an outer surface of the elongated body, a washer is positioned between the annular surface and an annular wall of a housing, the housing enclosing a portion of the elongated body, and a float spring encircles the elongated body and comprises a distal spring end abutting an annular shoulder of the elongated body and a proximal spring end retained in the housing.

12. The method of claim 11, further comprising urging the annular surface of the elongated body into contact with the washer.

13. The method of claim 12, wherein the float spring urges the annular surface of the elongated body into contact with the washer.

14. The method of claim 11, further comprising preventing axial movement of the elongated body relative to the housing.

15. The method of claim 14, wherein preventing axial movement of the elongated body relative to the housing comprises abutting a distal face of the washer against the annular wall of the housing.

16. The method of claim 11, further comprising preventing radial movement of the proximal spring end of the float spring.

17. The method of claim 11, wherein the annular surface of the elongated body is arcuate and the washer comprises an arcuate washer surface, the method further comprising causing relative movement between the arcuate annular surface and the arcuate washer surface.

18. The method of claim 11, further comprising imparting a radial restoring force to the elongated body when the elongated body is radially displaced from the centered position within the housing that urges the elongated body toward a centerline housing axis of the housing.

19. The method of claim 11, further comprising imparting an angular restoring force to the elongated body when the elongated body is angularly displaced from the centered position within the housing that urges the elongated body toward a centerline housing axis of the housing.

20. A self-centering plug for transferring fluid, the self-centering plug comprising:
an elongated body comprising an arcuate annular surface extending from an outer surface of the elongated body;
a washer comprising an arcuate washer surface contacting the arcuate annular surface, the washer located between the arcuate annular surface and an annular wall of a housing, the housing enclosing a portion of the elongated body; and
a float spring encircling the elongated body and comprising a distal spring end abutting an annular shoulder of the elongated body and a proximal spring end retained in the housing, wherein the float spring urges the annular surface of the elongated body into contact with the arcuate washer surface of the washer to provide a radial restoring force and an angular restoring force to the elongated body when the elongated body is radially displaced and angularly displaced from a centerline housing axis of the housing.
